(19) United States
(12) Patent Application Publication
(10) Pub. No.: US 2016/0041374 A1
(43) Pub. Date: Feb. 11, 2016

(54) Radiation Collector, Radiation Source and Lithographic Apparatus

(71) Applicant: ASML NETHERLANDS B.V., Veldhoven (NL)

(72) Inventors: Ivo VANDERHALLEN, Eindhoven (NL); Alexander Matthijs STRUYCKEN, Eindhoven (NL); Johannes Christiaan Leonardu FRANKEN, Knegsel (NL)

(73) Assignee: ASML Netherlands B.V., Veldhoven (NL)

(21) Appl. No.: 14/780,151

(22) PCT Filed: Mar. 24, 2014
(86) PCT No.: PCT/EP2014/055870

§ 371 Date: Sep. 25, 2015

Related U.S. Application Data
(60) Provisional application No. 61/812,961, filed on Apr. 17, 2013.

(51) Int. Cl. G02B 19/00; G02B 7/18; G02B 5/09; G02B 27/00; G03F 7/20; G02B 5/10

(52) U.S. Cl. CPC G02B 19/0023; G03F 7/70033; G02B 5/10; G02B 19/009; G02B 5/09; G02B 27/0006; G02B 7/1815

(57) ABSTRACT

A radiation collector (141) comprising a plurality of reflective surfaces (400-405), wherein each of the plurality of reflective surfaces is coincident with part of one of a plurality of ellipsoids (40-45), wherein the plurality of ellipsoids have in common a first focus (12) and a second focus (16), each of the plurality of reflective surfaces coincident with a different one of the plurality of ellipsoids, wherein the plurality of reflective surfaces are configured to receive radiation originating from the first focus (12) and reflect the radiation to the second focus (16). An apparatus (820) shown in FIG. 11 comprising a cooling system (832) and a reflector (831), wherein the cooling system is configured to cool the reflector, the cooling system comprising: a porous structure (823) situated in thermal contact with the reflector, wherein the porous structure is configured to receive a coolant in a liquid phase state; a condenser (825) configured to receive coolant from (826) the porous structure in a vapour phase state, condense the coolant thereby causing the coolant to undergo a phase change to a liquid phase state and output the condensed coolant in the liquid phase state for entry (827) into the porous structure.

### CROSS-REFERENCE TO RELATED APPLICATIONS

This application claims the benefit of U.S. provisional application 61/812,961, which was filed on 17 Apr. 2013, and which is incorporated herein in its entirety by reference.

### BACKGROUND OF THE INVENTION

1. Field of the Invention

The present invention relates to a radiation collector, a radiation source and a lithographic apparatus.

2. Related Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k1 is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

EUV radiation may be produced using a plasma. A radiation source for producing EUV radiation may excite a fuel to generate a plasma which emits EUV radiation. The plasma may be created, for example, by directing a laser beam at a fuel, such as droplets of a suitable material (e.g., tin), or a stream of a suitable gas or vapor, such as Xe gas or Li vapor. EUV radiation emitted by the plasma is collected using a radiation collector, which receives the EUV radiation and focuses the EUV radiation into a beam. The radiation source may include an enclosing housing or chamber arranged to provide a vacuum environment for the plasma. A radiation source which uses a laser beam in this way is typically termed a laser produced plasma (LPP) source. In an alternative radiation source, the plasma is generated by applying an electrical discharge across a gap at which fuel such as tin is located. Such a radiation source is typically termed a discharge produced plasma (DPP) source.

### BRIEF SUMMARY OF THE INVENTION

It may be desirable to provide a radiation collector which is novel and inventive over the prior art.

According to an aspect of the invention, there is provided a radiation collector comprising a plurality of reflective surfaces, wherein each of the plurality of reflective surfaces is coincident with part of one of a plurality of ellipsoids, wherein the plurality of ellipsoids have in common a first focus and a second focus, each of the plurality of reflective surfaces coincident with a different one of the plurality of ellipsoids, wherein the plurality of reflective surfaces are configured to receive radiation originating from the first focus and reflect the radiation to the second focus.

The radiation collector may be a normal incidence collector. The radiation collector may have a multilayer structure for reflecting EUV radiation.

An advantage of the invention is that it allows for some design flexibility in the configuration of the radiation collector.

The reflective surfaces may be disposed around an optical axis of the radiation collector.

The reflective surfaces may extend circumferentially around the optical axis.

The plurality of reflective surfaces may be joined by one or more intermediate surfaces.

Part of the plurality of reflective surfaces may also be joined only by one or more intermediate surfaces, whereas the rest of reflective surfaces may be joined by a coupling means such as a frame or a support without being coupled to each other by an intermediate surface. Also the plurality of reflective surfaces may be all joined by such coupling means only.

Each intermediate surface may be arranged substantially parallel to a direction from the first focus to the corresponding intermediate surface.

The intermediate surfaces may be undercut behind the reflective surfaces.

One or more holes (i.e. openings) may be provided in at least one of the one or more intermediate surfaces.

An inner reflective surface of the plurality of the reflective surfaces may be coincident with an inner ellipsoid of the plurality of ellipsoids.

The distance of each of the plurality of reflective surfaces from the optical axis may increase with the size of the ellipsoid which each reflective surface is coincident with.

The radiation collector may be configured such that an available length along the optical axis is provided in which a contaminant trap may be positioned in between the radiation collector and the first and second focuses, i.e. between the radiation collector and the first focus or between the radiation collector and the second focus.

The contaminant trap may be a rotating foil trap. Providing an available length in which a rotating foil trap may be provided is advantageous because it allows the amount of contamination incident upon the radiation collector to be reduced (compared with the case if the rotating foil trap was not present).

The plurality of reflective surfaces may have lengths which cause the radiation collector to act as a diffraction grating to infrared radiation or another radiation of a given wavelength.

The reflective surfaces may each have a length in a range from 0.1 to 5 mm, such as a length of around 1 mm.

The intermediate surfaces may each have a length of around cos θ(n+¼)λ_{IR} where n is an integer, λ_{IR} is the wavelength of infrared radiation to which the radiation collector acts as a diffraction grating and θ is the angle of incidence of infrared radiation on the reflective surfaces of the radiation collector.

The intermediate surfaces may each have a length in a range from 0.1 to 1 mm, such as a length of around 0.5 mm.

The plurality of reflective surfaces may comprise more than 10 reflective surfaces, preferably more than 50 reflective surfaces, even more preferably more than 100 reflective surfaces and most preferably more than 200 reflective surfaces.

Each intermediate surface may be arranged substantially parallel to a direction from the second focus to the intermediate surface.

The inner reflective surface may be coincident with an outer ellipsoid, where the inner reflective surface is the closest, of the plurality of reflective surfaces, to the optical axis and the outer ellipsoid is the largest of the plurality of ellipsoids.

The distance of each of the plurality of reflective surfaces from the optical axis, may decrease with the size of the ellipsoid with which each reflective surface is coincident.

According to a second aspect of the invention there is provided a radiation source comprising a radiation collector, the radiation collector comprising a plurality of reflective surfaces, wherein each of the plurality of reflective surfaces is coincident with part of one of a plurality of ellipsoids, wherein the plurality of ellipsoids have in common a first focus and a second focus, each of the plurality of reflective surfaces coincident with a different one of the plurality of ellipsoids, wherein the plurality of reflective surfaces are configured to receive radiation originating from the first focus and reflect the radiation to the second focus.

The plurality of reflective surfaces may be joined by one or more intermediate surfaces, and wherein one or more holes are provided in the one or more intermediate surfaces.

The radiation source may further comprise a gas source configured to deliver gas through the one or more holes.

A contaminant trap may be positioned in between the first focus and the radiation collector.

The contaminant trap may be a rotating foil trap.

Features of the first aspect of the invention may be combined with features of the second aspect of the invention.

According to a third aspect of the invention there is provided a lithographic apparatus arranged to project EUV radiation from a radiation source onto a substrate, wherein the radiation source comprises a radiation collector, the radiation collector comprising a plurality of reflective surfaces, wherein each of the plurality of reflective surfaces is coincident with part of one of a plurality of ellipsoids, wherein the plurality of ellipsoids have in common a first focus and a second focus, each of the plurality of reflective surfaces coincident with a different one of the plurality of ellipsoids, wherein the plurality of reflective surfaces are configured to receive radiation originating from the first focus and reflect the radiation to the second focus.

According to a fourth aspect of the invention there is provided a cooling system configured to cool a reflector, the cooling system comprising a porous structure situated in thermal contact with the radiation collector, wherein the porous structure is configured to receive a coolant in a liquid phase state, a condenser configured to receive coolant from the porous structure in a vapour phase state, condense the coolant thereby causing the coolant to undergo a phase change to a liquid phase state and output the condensed coolant in the liquid phase state for entry into the porous structure.

The porous structure may comprise a material through which a capillary structure extends.

The porous structure may comprise a metal.

The metal may comprise copper.

The cooling system may be configured such that coolant is distributed through the porous structure by capillary action.

The coolant may comprise methanol.

The cooling system may further comprise a non-porous sheet configured to seal the porous structure from the reflector.

The non-porous sheet may comprise a non-porous sheet of copper.

The cooling system may be configured to cool a reflector which forms part of a lithographic apparatus.

The may be configured to cool a radiation collector of a radiation source for a lithographic apparatus.

According to a fifth aspect of the invention there is provided an apparatus comprising a cooling system according to the fourth aspect and a reflector, wherein the cooling system is configured to cool the reflector.

The reflector may comprise a substrate and the cooling system may be configured to contact the substrate.

The substrate may comprise copper.

The substrate may comprise Al Si-40.

A surface of the substrate which is furthest from the porous layer may be provided with a smoothing layer configured to provide a smooth surface.

The smoothing layer may comprise nickel phosphate.

The reflector may form part of a lithographic apparatus.

The reflector may comprise a radiation collector according to the first aspect.

Features of the third aspect of the invention may be combined with features of the first and/or second aspects of the invention.

Features of the fourth aspect may be combined with features of the first, second or third aspects of the invention.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

Embodiments of the invention will now be described, by way of example only, with reference to the accompanying schematic drawings, in which:

FIG. 1 schematically depicts a lithographic apparatus according to an embodiment of the invention;

FIG. 2 is a more detailed view of the lithographic apparatus;

FIG. 3 is a schematic depiction of a radiation source SO including a radiation collector 14;

FIG. 4 is a front view of the radiation collector of FIG. 3;

FIG. 5 is a schematic depiction of radiation, incident on a far field location, which is reflected by the radiation collector of FIGS. 3 and 4;

FIG. 6a is a schematic graph of the intensity of radiation incident on the line C-D of FIG. 5, reflected from the radiation collector of FIGS. 3 and 4;

FIG. 6b is a schematic graph of the intensity of radiation incident on the line C-D of FIG. 5, reflected from the radiation collector of FIGS. 3 and 4, when the radiation collector contains aberrations;

FIG. 7 is a schematic depiction of a radiation source SO including a radiation collector 141 comprising six reflective surfaces;

FIG. 8 is a schematic graph of the intensity of radiation incident on the line C-D reflected from the radiation collector of FIG. 7;

FIG. 9 is a schematic depiction of a radiation source SO including an alternative embodiment of a radiation collector;

FIG. 10a is a schematic depiction of a portion of a radiation collector according to an embodiment of the invention;

FIG. 10b is a schematic depiction of a portion of a prior art radiation collector,

FIG. 10c is a schematic depiction of a portion of a radiation collector according to an alternative embodiment of the invention; and

FIG. 11 is a schematic depiction of a cooling system configured to cool a radiation collector.

The features and advantages of the present invention will become more apparent from the detailed description set forth below when taken in conjunction with the drawings. In the drawings, like reference numbers generally indicate identical, functionally similar, and/or structurally similar elements.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

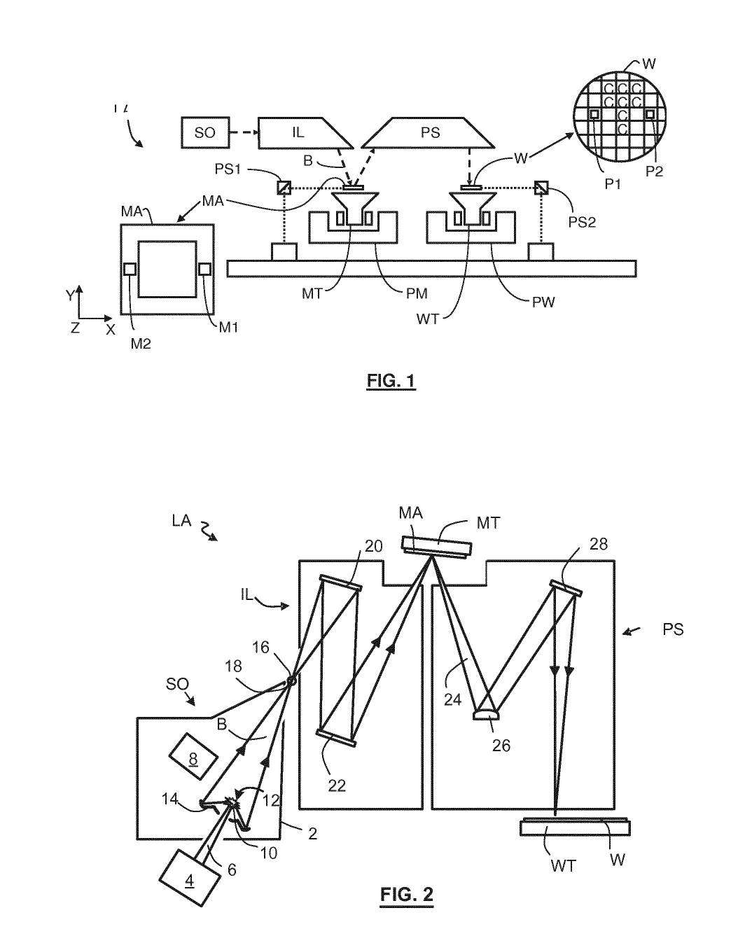

FIG. 1 schematically depicts a lithographic apparatus LA including a radiation source SO according to one embodiment of the invention. The apparatus further comprises:

an illumination system (illuminator) IL configured to condition a radiation beam B (e.g., extreme ultra violet (EUV) radiation).

a support structure (e.g., a mask table) MT constructed to support a patterning device (e.g., a mask or a reticle) MA and connected to a first positioner PM configured to accurately position the patterning device;

a substrate table (e.g., a wafer table) WT constructed to hold a substrate (e.g., a resist-coated wafer) W and connected to a second positioner PW configured to accurately position the substrate; and

a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus LA, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device is at a desired position, for example with respect to the projection system PS.

The term “patterning device” MA should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device MA may be transmissive or reflective. Examples of patterning devices include masks, programmable mirror arrays, and programmable LCD panels.

Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since gases may absorb a significant amount of EUV radiation. A vacuum environment may therefore be provided to substantially the entire path of the radiation beam B in the projection system, with the aid of a vacuum wall and vacuum pumps.

As here depicted, the apparatus may be of a reflective type (e.g., employing a reflective mask).

The lithographic apparatus LA may be of a type having two (dual stage) or more substrate tables WT (and/or two or more patterning device support structures MT). In such “multiple stage” machines, preparatory steps may be carried out on one or more substrate tables WT while one or more other substrate tables are being used for exposure.

Referring to FIG. 1, the illuminator IL receives an EUV radiation beam from the radiation source SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The radiation source SO may be part of an EUV radiation system including a laser, not shown in FIG. 1, for providing the laser beam exciting the fuel. The resulting plasma emits output radiation, e.g., EUV radiation, which is collected using a radiation collector, disposed in the radiation source. The laser and the radiation source may be separate entities, for example when a CO₂ laser is used to provide the laser beam for fuel excitation. In such cases, the laser is not considered to form part of the lithographic apparatus, and the laser beam is passed from the laser to the radiation source with the aid of a beam delivery system comprising, for example, suitable directing mirrors and/or a beam expander.

In an alternative method, often termed discharge produced plasma (“DPP”) the EUV emitting plasma is produced by using an electrical discharge to vaporise a fuel. The fuel may be an element such as xenon, lithium or tin which has one or more emission lines in the EUV range. The electrical discharge may be generated by a power supply which may form part of the radiation source or may be a separate entity that is connected via an electrical connection to the radiation source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

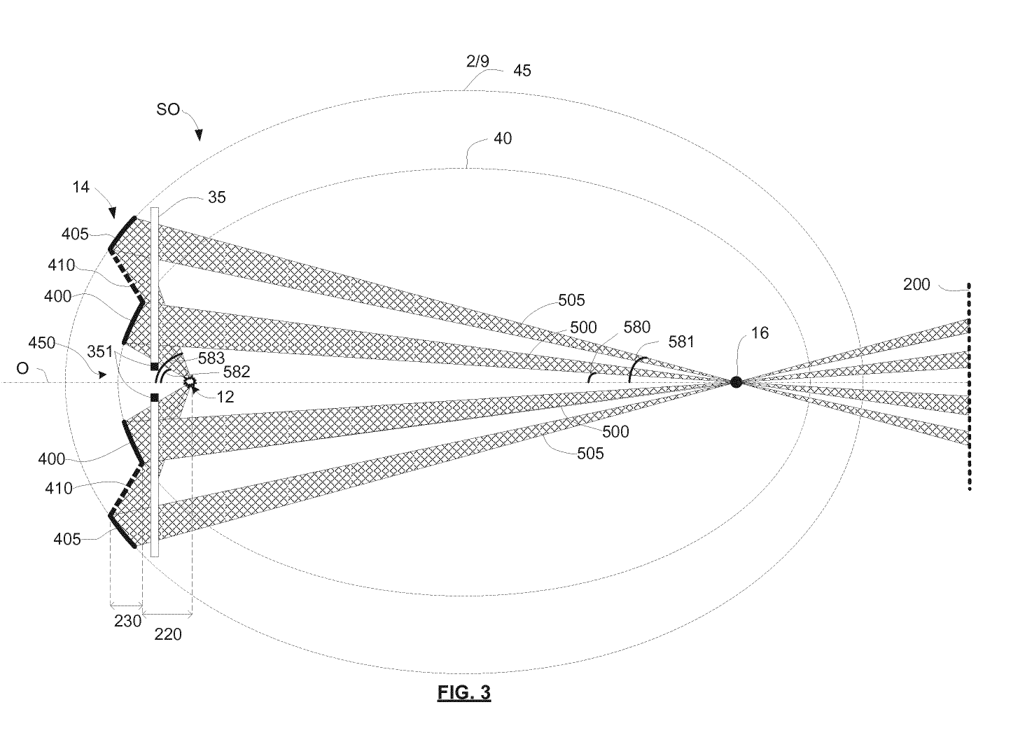

FIG. 2 shows the lithographic apparatus LA in more detail, including the radiation source SO, the illumination system IL, and the projection system PS. The radiation source SO is constructed and arranged such that a vacuum environment can be maintained in a housing 2 of the radiation source SO.

A laser 4 is arranged to deposit laser energy via a laser beam 6 into a fuel, such as tin (Sn) or lithium (Li) which is provided from a fluid emitter 8. Liquid (i.e., molten) tin (which may be in the form of droplets), or another metal in liquid form, is currently thought to be the most promising and thus likely choice of fuel for EUV radiation sources. The deposition of laser energy into the fuel creates a highly ionized plasma at a plasma formation region 12 which has electron temperatures of several tens of electron volts (eV). The energetic radiation generated during de-excitation and recombination of these ions is emitted from the plasma 10, collected and focused by a near normal incidence radiation collector 14 (sometimes referred to more generally as a normal incidence radiation collector). The radiation collector 14 depicted in FIG. 2 is one example of the shape which a radiation collector may take. Other embodiments of the radiation collector 14 may be differently shaped to the radiation detector depicted in FIG. 2. Embodiments of the radiation collector 14 are described in detail below. The radiation collector 14 may have a multilayer structure. The radiation collector 14 may be shaped according to a plurality of ellipsoids, the ellipsoids having two focuses. One first focus may be at the plasma formation region 12, and the other, second focus may be at the intermediate focus 16, discussed below.

A second laser (not shown) may be provided, the second laser being configured to preheat the fuel before the laser beam 6 is incident upon it. An LPP source which uses this approach may be referred to as a dual laser pulsing (DLP) source. Such a second laser may be described as providing a pre-pulse into a fuel target, for example to change a property of that target in order to provide a modified target. The change in property may be, for example, a change in temperature, size, shape or the like, and will generally be caused by heating of the target.

Although not shown in FIG. 1, the fuel emitter may comprise, or be in connection with, a nozzle configured to direct fuel droplets along a trajectory towards the plasma formation region 12.

Radiation B that is reflected by the radiation collector 14 is focused at point 16 to form an image of the plasma formation region 12 which in turn acts as a radiation source for the illuminator IL. The radiation B may comprise a plurality of sub-beams. The point 16 at which the radiation B is focused is commonly referred to as the intermediate focus, and the radiation source SO is arranged such that the intermediate focus 16 is located at or near to an opening 18 in the enclosing structure 2. An image of the radiation emitting plasma 10 is formed at the intermediate focus 16.

Subsequently, the radiation B traverses the illumination system IL, which may include a facetted field mirror device 20 and a facetted pupil mirror device 22 arranged to provide a desired angular distribution of the radiation beam B at the patterning device MA, as well as a desired uniformity of radiation intensity at the patterning device MA.

Upon reflection of the beam of radiation at the patterning device MA, held by the support structure MT, a patterned beam 24 is formed and the patterned beam 24 is imaged by the projection system PS via reflective elements 26, 28 onto a substrate W held by the wafer stage or substrate table WT.

More elements than shown may generally be present in the illumination system IL and projection system PS. Furthermore, there may be more mirrors present than those shown in the figures, for example there may be 1-6 additional reflective elements present in the projection system PS than shown in FIG. 2.

EUV radiation may alternatively be produced by a gas or vapor, for example Xe gas, Li vapor or Sn vapor. The gas or vapor is converted into a plasma 10 which emits radiation in the EUV range of the electromagnetic spectrum. The plasma 10 is created by, for example, an electrical discharge causing an at least partially ionized plasma.

Partial pressures of, for example, 10 Pa of Xe, Li, Sn vapor or any other suitable gas or vapor may be used to provide efficient generation of the radiation. In an embodiment, a plasma of excited tin (Sn) is provided to produce EUV radiation.

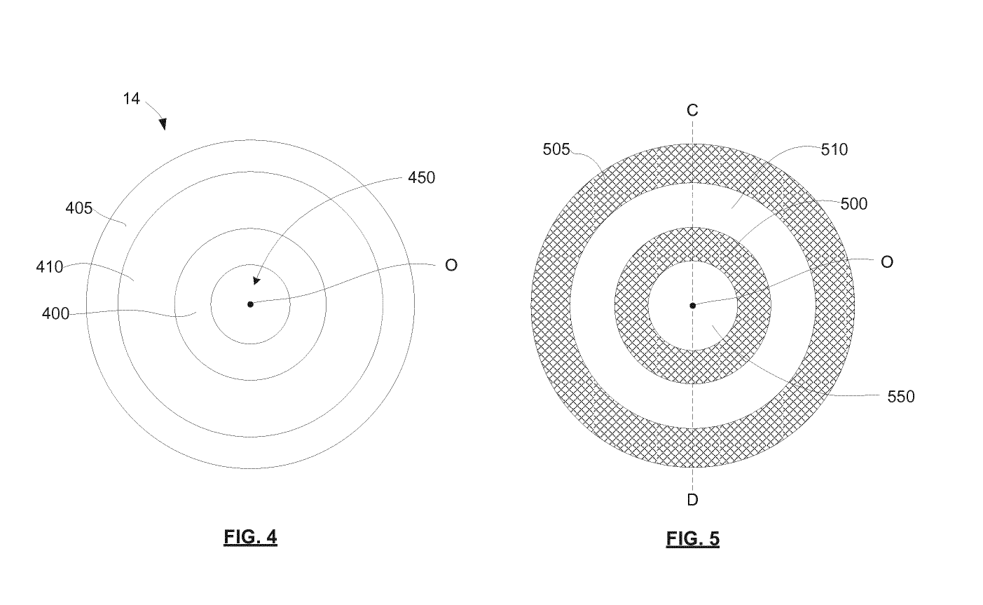

FIG. 3 schematically depicts an embodiment of a radiation source SO which may for example be a laser produced plasma (LPP) source. The radiation source SO comprises a radiation collector 14 and a contaminant trap 35, although the presence of the contamination trap 35 may be optional. EUV radiation is emitted from a plasma formation region 12. The radiation collector 14 comprises reflective surfaces which reflect EUV radiation emitted from the plasma formation region 12 towards an intermediate focus 16, such that radiation directed by the radiation collector 14 substantially converges at the intermediate focus 16. The reflective surfaces are disposed around an optical axis O of the radiation collector. A schematic depiction of the radiation collector 14, as viewed from the intermediate focus 16 is shown in FIG. 4.

The radiation collector 14 comprises surfaces 400, 405 and 410 which are disposed around the optical axis O of the radiation collector. In this embodiment the surfaces 400, 405 and 410 extend circumferentially around the optical axis O. A hole 450 is present at the centre of the radiation collector 14. One or more laser beams 6 (as shown in FIG. 2) may pass through the hole 450 in order to convert fuel to an EUV emitting plasma 10. The inner surface 400 (i.e., the surface nearest to the optical axis O) and the outer surface 405 (i.e., the surface furthest from the optical axis O) of the radiation collector 14 are shaped according to an inner ellipsoid 40 and an outer ellipsoid 45 respectively. The inner ellipsoid 40 and the outer ellipsoid 45 each have in common a first focus and a second focus, in each case the first focus is at or near to the plasma formation region 12 and the second focus is at or near to the location of the intermediate focus 16.

Although reference is made to a first focus at or near to the plasma formation region 12 and a second focus at or near to the location of the intermediate focus 16, it should be appreciated that the plasma formation region 12 and the intermediate focus 16 may not be precise points but may extend in one or more dimensions from their centres.

For example the plasma formation region 12 may have a diameter of approximately 600 microns (the EUV emitting plasma may have a diameter of approximately 600 microns). The extent of the intermediate focus 16 is limited by the size of the opening 18 in the enclosing structure 2 (see FIG. 2). The EUV radiation at the intermediate focus 16 may have a beam waist which is less than or equal to the diameter of the opening 18, such that substantially all of the EUV radiation at the intermediate focus 16 passes through the opening 18 and into the illuminator IL. This avoids significant loss of EUV radiation as the EUV radiation enters the illuminator IL. The opening 18 may have a diameter of approximately 6 mm. The radiation collector 141 may be configured such that an image of the EUV emitting plasma formed at the intermediate focus 12 has a diameter of approximately 6 mm. The diameter of the image depends upon the magnification provided by the radiation collector 141, which may be calculated for example as sin(angle no.582)/sin(angle no.580) or sin(angle no.583)/sin(angle no.581). The diameter of the image may be adjusted by adjusting the magnification provided by the radiation collector, for example to accommodate a different diameter opening 18 (see FIG. 2) at the intermediate focus.

The inner surface 400 is coincident with the circumference of part of the inner ellipsoid 40. The outer surface 405 is coincident with the circumference of part of the outer ellipsoid 45. The inner surface 400 and the outer surface 405 are reflective surfaces and reflect EUV radiation from the plasma formation region 12 towards the intermediate focus 16. The inner reflective surface 400 reflects EUV radiation to form an inner radiation sub-beam 500 and the outer reflective surface 405 reflects EUV radiation to form an outer radiation sub-beam 505. The sub-beams 500, 505 together form the radiation beam B depicted in FIG. 2.

The inner and outer reflective surfaces 400 and 405 are joined by an intermediate surface 410. The intermediate surface 410 is arranged substantially parallel to a direction from the plasma formation location 12 to the intermediate surface 410, for example formed by a plane that intersects the plasma formation location 12 and an end of a reflective surface (as shown in the cross-section of FIG. 3). The intermediate surface 410 is therefore substantially parallel to the direction of propagation of EUV radiation from the plasma formation region 12. The intermediate surface 410 therefore has substantially no EUV radiation incident upon it. The intermediate surfaces 410 may comprise one or more holes (as depicted in FIG. 3), through which a gas may be introduced to the radiation source SO. The gas may be introduced from a gas source. For example, the gas source may be configured to deliver a gas through the one or more holes. The gas source may deliver the gas from the intermediate surface 410 towards the EUV reflecting surface of the radiation collector 14. The gas may for example be hydrogen gas, a gas containing radicals, a halogen gas or an inert gas. The gas may form a gas buffer between the radiation collector and the plasma formation location 12 which may act to protect the radiation collector from contaminants originating from the fuel and the plasma formation region 12. For example contaminants may collide with molecules of the gas which may prevent the contaminants from reaching the radiation collector 14. The gas may additionally or alternatively act to clean any contaminants from the surfaces of the radiation collector 14.

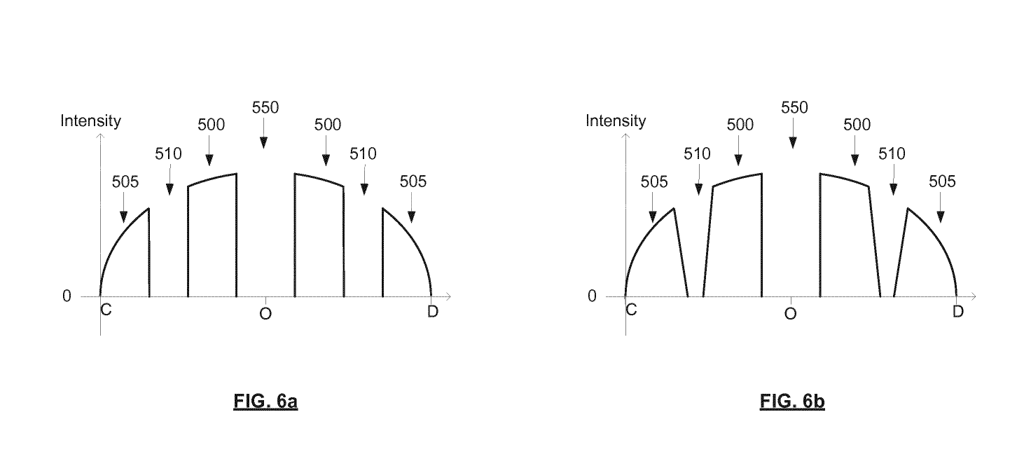

The radiation sub-beams 500 and 505 pass through the intermediate focus 16 to a far field location 200. The far field location 200 may, for example, be positioned at a distance of approximately 1 metre from the intermediate focus 16. A facetted field mirror device 20 as depicted in FIG. 2 may, for example, be provided at the far field location 200. FIG. 5 schematically depicts the EUV radiation incident on the far field location 200. The radiation sub-beams 500 and 505 have substantially circular inner and outer extents at the far field location 200 and are substantially concentric about the optical axis O. The radiation sub-beams 500 and 505 form an inner beam angle 580 and an outer beam angle 581 with the optical axis O (see FIG. 3). The inner beam angle 580 and the outer beam angle 581 define the inner and outer extent of the EUV radiation incident on the far field location 200. As mentioned above, a facetted field mirror device 20 may be provided at the far field location 200. The facetted field mirror device 20 along with a facetted pupil mirror device 22 may be arranged to reflect EUV radiation so as to provide a radiation beam having a desired angular distribution as well as a desired uniformity of radiation intensity. The facetted field mirror device 20 may be configured to receive EUV radiation having a specific inner beam angle 580 and a specific outer beam angle 581. In general, the inner beam angle 580 and the outer beam angle 581 may be determined by design restrictions of the radiation source SO and the illuminator IL.

A shadow ring 510 in which substantially no EUV radiation is present, extends between the radiation sub-beams 500 and 505. A central shadow region 550 in which substantially no EUV radiation is present is encompassed by the inner extent of the inner radiation sub-beam 500.

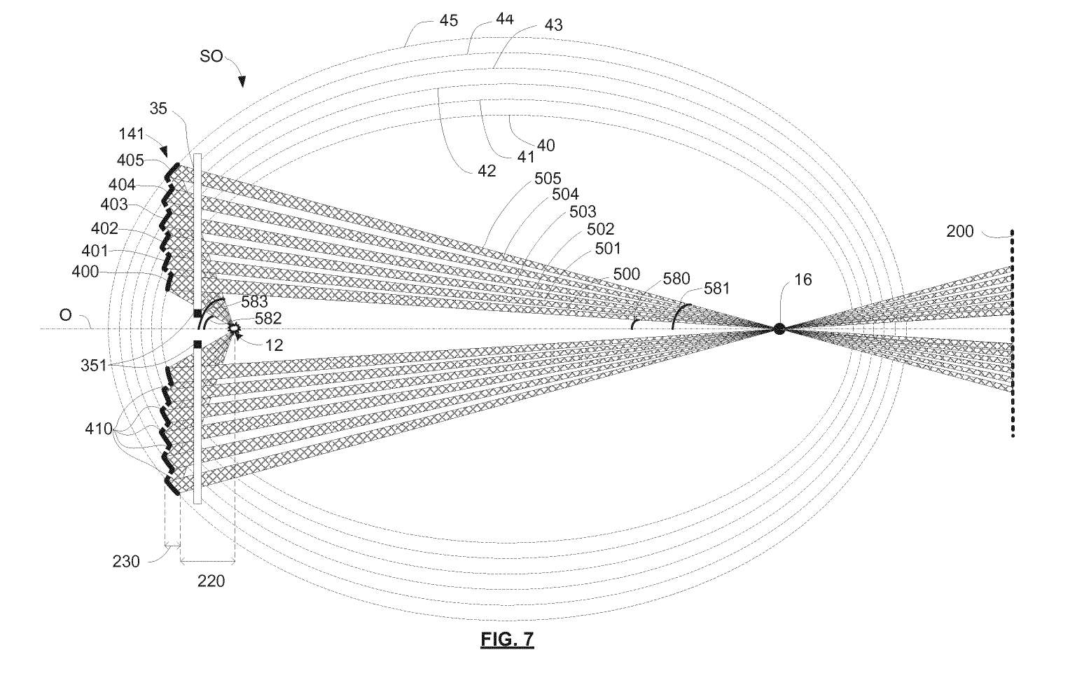

FIG. 6a is a schematic graph of the intensity of EUV radiation incident on the far field location 200, along the line C-D, depicted in FIG. 5. The intensity of the radiation sub-beams 500 and 505 incident on the far field location 200, increases towards the optical axis O. This may be due to non-isotropic emission of EUV radiation from plasma formation region 12. For example, the intensity of EUV radiation emitted, from the plasma formation region 12, along the inner radiation collector angle 582 may be greater than the intensity of EUV radiation emitted along the outer radiation collector angle 583. The boundaries between the radiation sub-beams 500 and 505 and the shadow ring 510 at the far field location 200 are depicted in FIGS. 5 and 6a as being abrupt transitions from substantial intensities of EUV radiation to substantially no EUV radiation and vice-versa. In practice however the reflective surfaces 400 and 405 may contain aberrations from the elliptical shapes of the ellipsoids 40 and 45. Aberrations in the reflective surfaces 400 and 405 may cause some EUV radiation to be reflected into the shadow ring 510 near to the edges of the shadow ring 510. FIG. 6b is a schematic graph of the intensity of radiation incident on the far field location 200, along the line C-D (as also shown in FIG. 5), when aberrations in the reflective surfaces 400 and 405 cause some EUV radiation to be reflected into the shadow ring 510.

Referring again to FIG. 3, a contaminant trap 35 is positioned in between the plasma formation region 12 and the radiation collector 14. The contaminant trap 35 depicted in FIG. 3 and described below is a rotating foil trap, but other forms of contaminant trap may be used. The contaminant trap 35 may have a substantially circular outer perimeter and may have a hole extending through its centre as depicted in FIG. 3. The hole may allow one or more laser beams 6 to pass through the contaminant trap 35 in order to convert fuel to an EUV emitting plasma 10. The contaminant trap 35 comprises a series of foil blades which extend radially outwards from the outer perimeter of the hole to the outer perimeter of the contaminant trap 35. The contaminant trap 35 is rotated such that the foil blades may collide with contaminants passing through the contaminant trap, thereby trapping the contaminants.

The contaminant trap 35 is configured to trap contaminants from the fuel and the plasma formation region 12, and prevents the trapped contaminants from reaching the radiation collector 14. Contaminants from the fuel and the plasma formation region 12, may include atoms, ions and particles of the fuel. Contaminants which reach the radiation collector 14 may deposit on the reflective surfaces 400, 405 of the radiation collector 14 and may reduce the reflectivity of the reflective surfaces and therefore reduce the total amount of EUV radiation which is reflected by the radiation collector 14. The foil blades of the contaminant trap 35 may have a sufficiently small cross-sectional area that EUV radiation passing through the contaminant trap 14 is not significantly obstructed by the contaminant trap 35. The contaminant trap 35 does not therefore significantly reduce the total amount of EUV radiation reflected to the intermediate focus 16 and the far field location 200. The contaminant trap 35 may however have an inner portion 351 which obstructs EUV radiation. The inner portion 351 may, for example, include a motor or other driving means configured to rotate the contaminant trap 35. The inner portion 351 defines an inner radiation collector angle 582 which is the minimum angle at which EUV radiation emitted from the plasma formation region 12 may be collected by the radiation collector 14 and reflected to the intermediate focus 16. The inner radiation collector angle may, for example, be approximately 15 degrees. The inner reflective surface 400 collects radiation at the inner radiation collector angle 582 and is positioned sufficiently close to the plasma formation region 12 in order to direct the radiation to the intermediate focus 16 along the inner beam angle 580. The outer extent of the reflective surface 405 defines an outer radiation collector angle 583, which is the maximum angle at which EUV radiation emitted from the plasma formation region 12 is collected by the radiation collector 14 and reflected to the intermediate focus 16.

The plasma 10 may reach very high temperatures which may, for example, exceed 1000° C. It is therefore desirable to position a contaminant trap 35 at a sufficient distance from the plasma formation region 12, such that the contaminant trap 35 is not exposed to high heat loads from the plasma formation region 12, which may damage the contaminant trap 35.

Some contaminants which are trapped by the contaminant trap 35 may subsequently be ejected from the contaminant trap 35. The contaminants may be ejected in any direction but may in particular be ejected radially outwards from the contaminant trap 35 (due to the rotational motion of the contaminant trap). It is therefore desirable to position the contaminant trap 35 at a sufficient distance from the radiation collector 14 that substantially no contaminants which are ejected from the contaminant trap 35, reach the radiation collector 14. In particular it is desirable that there is little or no axial overlap between the extent of the radiation collector along the optical axis O, and the extent of the contaminant trap 35 along the optical axis O (this would lead to radially ejected contamination being directly incident upon the radiation collector). It is therefore desirable to provide an available length along the optical axis O, in between the radiation collector and the plasma formation location 12, in which a contaminant trap 35 may be positioned.

The available length in which a contaminant trap may be positioned (without there being any axial overlap of the contaminant trap and the radiation collector) may depend on the shape and the positioning of the radiation collector 14, and in particular on the depth 230 of the radiation collector 14 along the optical axis O. For example the radiation collector 14 depicted in FIG. 3, and shaped according to ellipsoids 40 and 45, provides an available length 220 in which the contaminant trap 35 may be positioned between the plasma formation region 12 and the radiation collector 14. There is therefore no axial overlap between the radiation collector 14 and the contaminant trap 35, depicted in FIG. 3.

It is desirable to provide a sufficient available length 220 between the radiation collector 14 and the plasma formation region 12, such that a contamination trap 35 may be positioned at a sufficient distance from the plasma formation region 12 to avoid damaging heat loads from the plasma 10 and at a sufficient distance from the radiation collector 14 such that there is no axial overlap between the radiation collector 14 and the contaminant trap 35. The radiation collector 14 depicted in FIG. 3 and shaped according to the two ellipsoids 40 and 45 is therefore advantageous in that it provides a sufficient available length 220 between the plasma formation region 12 and the radiation collector 14 whilst maintaining the inner and outer beam angles 580 and 581 and collecting radiation at the inner radiation collector angle 582.

The available length 220 provided by the embodiment depicted in FIG. 3 is advantageous when compared with a prior art radiation collector comprising a single reflective surface. Such a prior art radiation collector will be shaped according to a single ellipsoid, and will have a greater depth along the optical axis O than a radiation collector according to an embodiment of the invention. Such a prior art radiation collector may not provide a sufficient available length between the plasma formation region 12 and the radiation collector in which a contaminant trap may be positioned. For example, a radiation collector comprising a single reflective surface could be constructed to collect EUV radiation over the same angular range as the radiation collector 14 depicted in FIG. 3. Such a radiation collector could, for example, comprise a single reflective surface shaped according to the ellipsoid 40. However such a radiation collector would, in order to collect radiation over the same angular range, extend around ellipsoid 40 away from the optical axis O, thereby increasing the depth 230 of the radiation collector and reducing the available length 220. In order for the radiation collector to provide EUV radiation having an outer beam angle equal to the outer beam angle 580 depicted in FIG. 3, the reflective surface 400 would need to extend around the ellipsoid 40 such that it extends beyond the plasma formation region 12 along the optical axis O. No length would therefore be provided between the radiation collector 14 and the plasma formation region 12 in which to position a contaminant trap 35. If a contaminant trap were to be provided, there would be an axial overlap between the radiation collector 14 and the contaminant trap 35. This would cause contamination radially ejected from the contaminant trap to be incident upon the collector. This problem is avoided by embodiments of the invention.

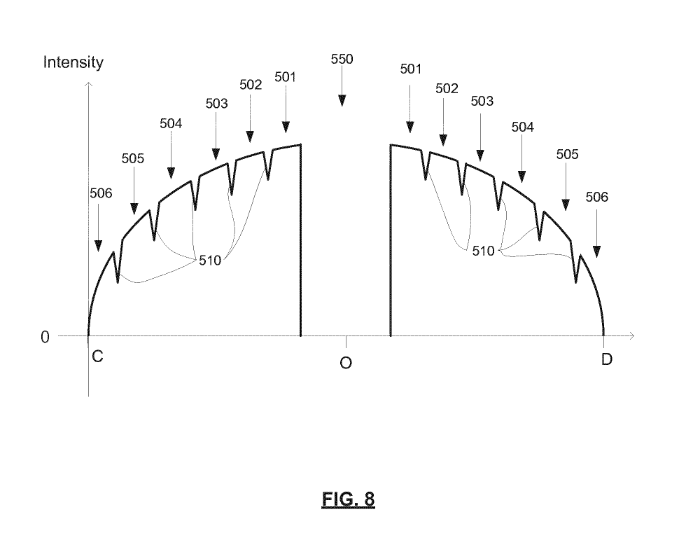

A radiation collector according to an embodiment of the invention may comprise more than two reflective surfaces. Each of the more than two reflective surfaces may be coincident with part of a different ellipsoid. FIG. 7 schematically depicts a radiation source SO according to an embodiment of the invention comprising a radiation collector 141. The radiation collector 141 comprises six reflective surfaces 400-405 shaped wherein each of the reflective surfaces 400-405 is coincident with one of six ellipsoids 40-45. In an embodiment, the ellipsoids 40-45 all have in common a first ellipse focus and a second ellipse focus. In each case the first focus is at or near to the plasma formation region 12 and the second focus is at or near to the location of the intermediate focus 16. The reflective surfaces are disposed around an optical axis O of the radiation collector. The reflective surfaces 400-405 extend substantially circumferentially around the optical axis O.

The reflective surfaces 400-405 are joined by a series of intermediate surfaces 410. Each intermediate surface 410 is arranged substantially parallel to a direction from the plasma formation location 12 to the intermediate surface 410. The intermediate surfaces 410 are therefore substantially parallel to the direction of propagation of EUV radiation from the plasma formation region 12. The intermediate surfaces 410 therefore have substantially no EUV radiation incident upon them. One or more holes may be provided in one or more of the intermediate surfaces 410 (as depicted in FIG. 7), through which a gas may be introduced. The gas may be hydrogen gas which may act to protect the radiation collector 141 from contaminants originating from the fuel and the plasma formation region 12. The gas may additionally or alternatively act to clean any contaminants from the surfaces of the radiation collector 141. The gas may be delivered through the one or more holes by a gas source (not shown), the gas source being configured to deliver gas through the one or more holes.

The reflective surfaces 400-405 reflect EUV radiation to form radiation sub-beams 500-505 respectively. The radiation sub-beams 500-505 pass through an intermediate focus 16 and are incident on a far field location 200. The radiation sub-beams 500-505 form an inner beam angle 580 and an outer beam angle 581 with the optical axis O. The inner beam angle 580 and the outer beam angle 581 define the inner and outer extent of the EUV radiation incident on the far field location 200.

The radiation collector 141 depicted in FIG. 7 collects EUV radiation over the same angular range (between the inner radiation collector angle 582 and the outer radiation collector angle 583) as the radiation collector 14 depicted in FIG. 3. The radiation collector 141 also reflects EUV radiation to form radiation sub-beams 500-505 which form the same inner beam angle 580 and the same outer beam angle 581 with the optical axis O, as the radiation sub-beams 500, 505 formed by the radiation collector 14. EUV radiation collected by the radiation collector 141 therefore has the same inner and outer extent at the far field location 200 as EUV radiation collected by the radiation collector 14. The radiation collector 141 however has a smaller depth 230 along the optical axis O then the radiation collector 14. A smaller depth 230 may increase the length 220 between the plasma formation region 12 and the radiation collector, in which a contaminant trap 35 may be positioned.

FIG. 8 is a schematic graph of the intensity of EUV radiation, collected by the radiation collector 141, incident on the far field location 200, along the line C-D (see FIG. 5). The radiation intensity distribution includes a central shadow region 550 in which substantially no EUV radiation is present. Shadow rings 510 extend between the radiation sub-beams 500-505. The shadow rings 510 are caused by the intermediate surfaces 410 of the radiation collector 141 on which substantially no EUV radiation is incident and therefore from which substantially no EUV radiation is reflected. The shadow rings 510 cause troughs in the EUV radiation intensity as can be seen in FIG. 8. However, aberrations in the reflective surfaces cause some EUV radiation to be reflected into the shadow rings 510. The intermediate surfaces of the radiation collector 141 are sufficiently short and hence the shadow rings 510 have a sufficiently small radial extent that EUV radiation which is reflected into the shadow rings 510, cause the troughs in the EUV radiation intensity caused by the shadow rings 510 to not drop to zero.

In general the width and the depth of troughs in the radiation intensity reflected from a radiation collector may be reduced by reducing the length of the intermediate surfaces of the radiation collector which join reflective surfaces of the radiation collector. The length of the intermediate surfaces may be reduced by increasing the number of reflective surfaces which form the radiation collector and hence increasing the number of ellipsoids with which the reflective surfaces of the radiation collector are coincident.

For example, the radiation collector 14 (depicted in FIG. 3) comprises two reflective surfaces 400 and 405 which are each coincident with one of two ellipsoids 40 and 45. The intermediate surface 410 which joins the reflective surfaces 400, 405 causes a shadow ring 510 which has a sufficiently large radial extent that a significant trough is caused in the radiation intensity distribution resulting from the radiation collector 14 (depicted in FIG. 6b). In contrast, the radiation collector 141 (depicted in FIG. 7) comprises six reflective surfaces 400-405, which are each coincident with one of six ellipsoids 40-45. The intermediate surfaces 410 which join the reflective surfaces 400-405 of the radiation collector 141 are therefore shorter than the intermediate surface 410 which joins the reflective surfaces 400, 405 of the radiation collector 14. Consequently the shadow rings 410 formed by the radiation collector 141 have a smaller radial extent than the shadow ring formed by the radiation collector 14. The troughs in the radiation intensity distribution reflected from the radiation collector 141 are therefore narrower and shallower than the troughs in the radiation intensity distribution reflected from the radiation collector 14.

It may be desirable to provide EUV radiation having a substantially smooth radiation intensity distribution (either side of the central shadow region) at the far field location 200. This may allow, for example, a facetted field mirror device 20 and a facetted pupil mirror device 22 to provide a radiation beam having a desired angular distribution as well as a desired uniformity of radiation intensity. Increasing the number of reflective surfaces of the radiation collector and therefore increasing the number of ellipsoids according to which a radiation collector is shaped may eventually reduce the width and depth of any troughs in the radiation intensity distribution reflected from the radiation collector such that the troughs become negligible. A substantially smooth radiation intensity distribution containing no substantial troughs may therefore be achieved by forming a radiation collector from many reflective surfaces shaped according to many ellipsoids. For example a radiation collector may comprise more than 6 reflective surfaces, shaped according to more than 6 ellipsoids (i.e., more than are shown in FIG. 7). Some embodiments of the radiation collector may, for example, comprise more than 10 reflective surfaces shaped according to more than 10 ellipsoids. Some embodiments of the radiation collector may, for example, comprise more than 30 reflective surfaces shaped according to more than 30 ellipsoids. As mentioned above, increasing the number of reflective surfaces provides the advantage that troughs between radiation reflected from reflective surfaces are reduced. A practical limit to the number of reflective surfaces may arise from the maximum angle 583 at which the radiation collector 141 receives radiation (which may be referred to as the opening angle 583 of the radiation collector), combined with manufacturing limitations to the number of reflective surfaces which may be provided over a particular angular range.

In addition to EUV radiation, a radiation collector may also be exposed to infrared radiation or (D)UV radiation. The infrared radiation may originate from one or more infrared lasers which are used to convert fuel to an EUV emitting plasma 10. Infrared radiation may be reflected by the radiation collector and directed through the intermediate focus 16 to the far field location 200. Infrared radiation which reaches the far field location 200 may cause undesirable heating of components of the lithographic apparatus. It may therefore be desirable to reduce any infrared radiation which is reflected by the radiation collector and directed towards the intermediate focus 16. This may be achieved by forming grooves or ridges in the reflective surfaces of a radiation collector such that the reflective surfaces act as diffraction gratings to infrared radiation and therefore do not substantially reflect infrared radiation towards the intermediate focus 16.

The reflective surfaces of a radiation collector, according to an embodiment of the invention, may have lengths which cause the radiation collector to act as a diffraction grating to infrared radiation. The radiation collector may act as a diffraction grating to infrared radiation if the lengths of the reflective surfaces are of the order of the wavelength of the infrared radiation. Since the wavelength of EUV radiation is substantially shorter than the wavelength of infrared radiation, the lengths of the reflective surfaces and the intermediate surfaces may be such that the radiation collector reflects EUV radiation towards the intermediate focus 16 but acts as a diffraction grating to infrared radiation and therefore does not substantially reflect infrared radiation towards the intermediate focus 16. Such a radiation collector may for example comprise reflective surfaces having lengths which are of the order of the wavelength of the infrared radiation. The intermediate surfaces may also have lengths which are of the order of the wavelength of the infrared radiation.

The radiation collectors 14 and 141 depicted in FIGS. 3 and 7 respectively, both comprise a plurality of reflective surfaces 400-405, wherein each of the plurality of reflective surfaces is coincident with one of a plurality of ellipsoids 40-45. The plurality of ellipsoids 40-45 have in common a first focus and a second focus. The first focus is at or near the plasma formation location 12 and the second focus is at or near the intermediate focus 16. The plurality of reflective surfaces 400-405 are configured to receive radiation from the first focus and reflect the radiation to the second focus. The plurality of reflective surfaces 400-405 are joined by one or more intermediate surfaces 410. Each intermediate surface 410 is arranged substantially parallel to a direction from the first focus to the intermediate surface 410. The distance of the plurality of reflective surfaces from the optical axis O, increases with the size of the ellipsoid which each reflective surface is coincident with. The inner reflective surface 400 of the plurality of the reflective surfaces is therefore coincident with an inner ellipsoid 40 of the plurality of ellipsoids.

The radiation collectors 14 and 141 have a depth 230 along the optical axis O. The radiation collectors 14 and 141 are shaped so as to reduce the depth 230 of the radiation collectors. The radiation collectors 14 and 141 consequently have a flatter profile than a radiation collector comprising a single reflective surface shaped according to a single ellipsoid. The radiation collectors 14 and 141 are configured such that an available length 220 along the optical axis O is provided in which a contaminant trap 35 may be positioned in between the radiation collector and the first and second focuses. In general the greater the number of reflective surfaces which a radiation collector comprises the smaller the achievable depth 230 of the radiation collector and the flatter its profile (for given radiation collector and beam angles). In general, the smaller the achievable depth 230, the greater the available length 220.

A radiation collector according to an embodiment of the invention may however be shaped to have a substantially non-flat profile.

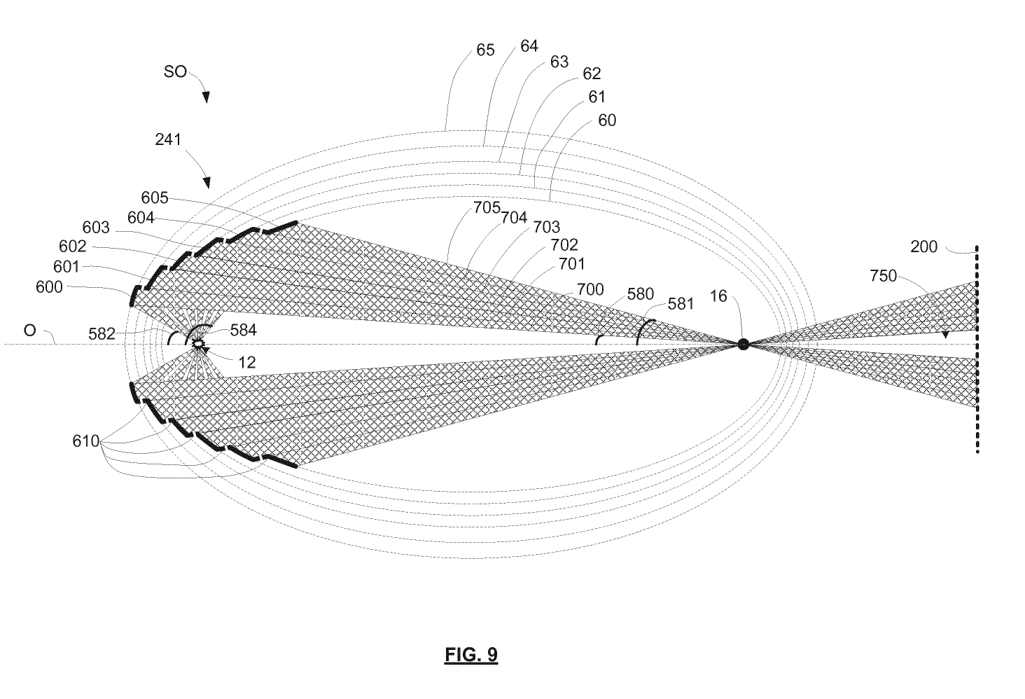

FIG. 9 schematically depicts an embodiment of a radiation source SO comprising a radiation collector 241 having a substantially non-flat profile. The radiation collector 241 is shaped according to ellipsoids 60-65. In an embodiment, the ellipsoids 60-65 all have in common a first focus and a second focus, in each case the first focus is at or near to the plasma formation region 12 and the second focus is at or near to the location of the intermediate focus 16. The radiation collector 241 comprises reflective surfaces 600-605 which are coincident with the ellipsoids 60-65 respectively.

The reflective surfaces 600-605 each reflect EUV radiation to form radiation sub-beams 700-705 respectively. The radiation sub-beams 700-705 pass through the intermediate focus 16 and are incident on a far field location 200. The radiation sub-beams 700-705 form an inner beam angle 580 and an outer beam angle 581 with the optical axis O.

In the embodiment depicted in FIG. 9, the ellipsoid 65 is the same as the ellipsoid 40, depicted in FIGS. 3 and 7. The reflective surface 600 therefore collects radiation at the same inner radiation collector angle 582 as the reflective surface 400. The inner radiation sub-beam 700 also forms the same inner beam angle 580 with the optical axis as the inner radiation sub-beam 500. The radiation collector 241 extends to collect EUV radiation up to and including an outer radiation collector angle 584 such that the outer radiation sub-beam 705 forms the same outer beam angle 581 with the optical axis as the outer radiation sub-beam 505. The radiation collector 241 therefore forms radiation sub-beams 700-705 having the same inner and outer extent at the far field location 200 as the radiation sub-beams 500-505 formed by the radiation collectors 14 and 141.

The reflective surfaces are joined by a series of intermediate surfaces 610. Each intermediate surface 610 is substantially parallel to a direction from the intermediate focus 16 to the intermediate surface 610. Each intermediate surface is therefore substantially parallel to the direction of propagation of EUV radiation which has been reflected from the reflective surfaces 600-605 towards the intermediate focus 16. The intermediate surfaces 610 therefore have EUV radiation from the plasma formation region 12 incident upon them which is not subsequently reflected to the intermediate focus 16. This may lead to some loss of EUV radiation at the intermediate focus 16 compared to the EUV radiation reflected to the intermediate focus 16 from the radiation collectors 14 and 141. However the radiation collector 241 collects radiation from the plasma formation region 12 over a greater angular range than the radiation collectors 14 and 141. The greater angular range of collection of the radiation collector 241 may compensate for any EUV radiation lost due to the intermediate surfaces 610 of the radiation collector 241.

The intermediate surfaces 610 may comprise one or more holes in the intermediate surfaces 610 (as depicted in FIG. 9), through which a gas may be introduced. The gas may be hydrogen gas which may act to protect the radiation collector 241 from contaminants originating from the fuel and the plasma formation region 12. The gas may additionally or alternatively act to clean any contaminants from the surfaces of the radiation collector 241. The gas may be delivered through the one or more holes by a gas source.

Since the intermediate surfaces 610 are substantially parallel with the direction of propagation of EUV radiation reflected from the reflective surfaces 600-605, the radiation sub-beams 700-705 have substantially no shadow rings between them. An intensity distribution of EUV radiation at the far field location 200 (either side of a central shadow region 750) is therefore substantially continuous.

The radiation collector 241 has a different shape to the radiation collectors 14 and 141. Each intermediate surface 610 is arranged substantially parallel to a direction from the second focus (being at or near the location of the intermediate focus) to the intermediate surface 610. The distance of the plurality of reflective surfaces 600-605 from the optical axis O, decreases with the size of the ellipsoid which each reflective surface is coincident with. The inner reflective surface 600 (i.e., the one closest to the optical axis O) of the plurality of the reflective surfaces is therefore coincident with an outer ellipsoid 600 of the plurality of ellipsoids.

The substantially different shape of the radiation collector 241 to the radiation collectors 14 and 141 results in substantially different angles of incidence and reflection which EUV radiation, from the plasma formation region 12, forms with the reflective surfaces of the respective radiation collectors. The reflectivity of a reflective surface may vary as a function of the angle of incidence of radiation incident upon the reflective surface. For example, a reflective surface may be most reflective when the angle of incidence is close to a normal angle. The angles of incidence which EUV radiation forms with the reflective surfaces of the radiation collectors 14 and 141 may be closer to a normal angle than the angles of incidence which EUV radiation forms with the reflective surfaces of the radiation collector 241. A radiation collector with a shape equivalent to the shapes of the radiation collectors 14 and 141 may therefore reflect more EUV radiation from the plasma formation region 12 than a radiation collector with a shape equivalent to the shape of the radiation collector 241.

The radiation collectors 14 and 141 allow for an available length 220 between the plasma formation region 12 and the radiation collectors 14 and 141, in which a contaminant trap 35 may be positioned. The radiation collector 241, however does not allow for an available length between the plasma formation region 12 and the radiation collector 241. Therefore if a contaminant trap were to be positioned in between the plasma formation region 12 and the radiation collector 241, the contaminant trap would axially overlap with the radiation collector 241. As a result, any contamination expelled by the contaminant trap in the radial direction (which may occur due to rotation of the contaminant trap) would be incident upon the radiation collector 241.

Embodiments of the invention have been described which collect EUV radiation between an inner radiation collector angle 582 and an outer radiation collector angle 583, 584 and reflect the EUV radiation into radiation sub-beams forming an inner beam angle 580 and an outer beam angle 581 with the optical axis O. Other embodiments of the invention may however have inner and outer radiation collector angles and inner and outer beam angles other than those described above and depicted in the figures. These angles may be determined according to a desired inner and outer extent of radiation incident on the far field location 200 and according to the relative geometries of the radiation collector, intermediate focus 16 and the far field location 200. For example if the far field location 200 and/or the intermediate focus 16 were to be moved along the optical axis O relative to the radiation collector, then it may be desirable to alter the inner and outer beam angles in order to maintain the inner and outer extent of radiation incident on the far field location 200. Additionally or alternatively for some embodiments of the invention it may be desirable to alter the inner and outer extent of radiation incident on the far field location 200, according to the configuration of the far field location 200. In general the inner beam angle 580, the outer beam angle 581, the inner radiation collector angle 582 and the outer radiation collector angle 583, 584 may be determined and limited by the design of the radiation source SO and the illuminator IL. These angles may therefore be altered by altering the design of the radiation collector in order to meet design restrictions of the radiation source SO and the illuminator IL.

As was described above, infrared radiation may be incident on a radiation collector in an EUV radiation source SO (e.g. the radiation collectors 14, 141, 241 depicted in FIGS. 2, 3, 7 and 9). For example, one or more infrared lasers (e.g. a CO₂ laser) may be incident on a plasma formation location 12 in order to excite fuel to form an EUV emitting plasma. Some of the infrared radiation from the one or more infrared lasers may be reflected by the plasma and/or the fuel at the plasma formation location 12 such that it is incident on a radiation collector. A portion of infrared radiation which is incident on a radiation collector may be reflected by the radiation collector towards an intermediate focus 16. Infrared radiation which is reflected towards the intermediate focus 16 may enter an illumination system IL (depicted in FIG. 2) and may subsequently be reflected to further optical components of a lithographic apparatus LA.

Infrared radiation which is reflected towards the intermediate focus 16 and which enters the illumination system IL may be absorbed by optical components in the illumination system IL and/or by other optical components of a lithographic apparatus LA. Absorption of infrared radiation by optical components may cause the optical components to be heated by the infrared radiation. Heating of the optical components may cause expansion of all or part of the optical components which may alter the optical properties of the optical components. Alteration of the optical properties of optical components may affect the EUV radiation beam which propagates through the lithographic apparatus and may ultimately affect a pattern which is applied to a substrate W by a patterned EUV radiation beam.

It is therefore desirable to reduce the amount of infrared radiation which is reflected towards the intermediate focus 16 by a radiation collector such that the amount of infrared radiation which is incident on optical components of a lithographic apparatus is reduced. In the embodiments of radiation collectors 14, 141, 241 depicted in FIGS. 2, 3, 7 and 9, the amount of infrared radiation which is reflected towards the intermediate focus 16 may be reduced by configuring the radiation collectors 14, 141, 241 such that they act as diffraction gratings to infrared radiation. For example the plurality of reflective surfaces which make up a radiation collector may have lengths which are of the order of the wavelength of infrared radiation such that infrared radiation is diffracted by the radiation collector as opposed to being reflected to the intermediate focus 16.

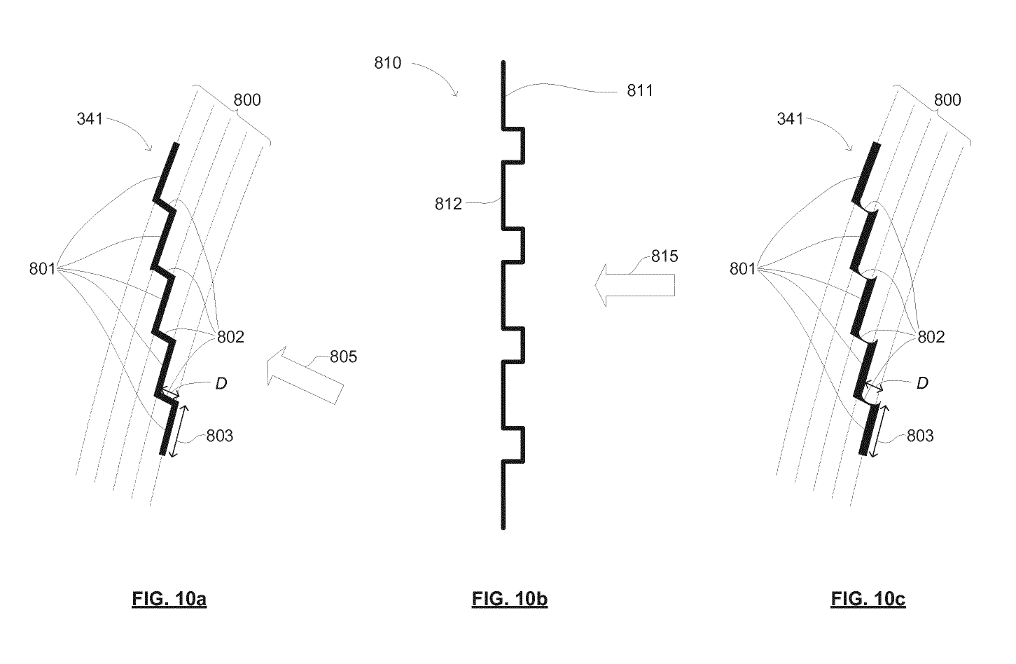

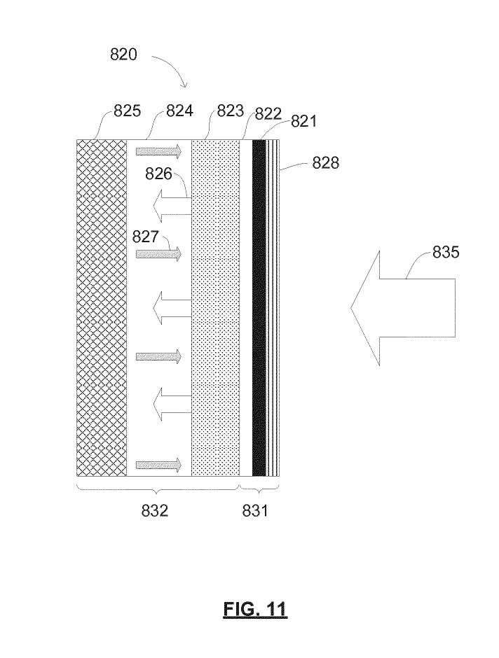

FIG. 10a is a schematic representation of a close up view of a portion of a radiation collector 341 according to an embodiment of the invention. The radiation collector 341 comprises a plurality of reflective surfaces 801 each of which are coincident with a part of one of a plurality of ellipsoids 800. The plurality of ellipsoids 800 each have a common first focus and second focus (not shown). The first focus is at or near to a plasma formation region 12 of a radiation source SO of which the radiation collector 341 forms a part. The second focus is at or near to the location of an intermediate focus 16 of the radiation source SO. The reflective surfaces 801 are configured to receive EUV radiation (denoted by the arrow 805) from the plasma formation region 12 and reflect the radiation to the intermediate focus 16.

The plurality of reflective surfaces 801 are joined by a plurality of intermediate surfaces 802. The intermediate surfaces 802 may, for example, include holes (not shown) though which a gas flow (e.g. a hydrogen gas flow) may be introduced as was described above, for example, with reference to FIG. 3.

The arrangement of the reflective surfaces 803 and the intermediate surfaces 802 result in the radiation collector 341 having a periodic structure which may be characterised by a pitch 803 and a depth D as indicated in FIG. 10a. The pitch 803 is equivalent to the length of each reflective surface 801 and the depth D is equivalent to the length of the intermediate surfaces 802. The pitch 803 and the depth D of a radiation collector 341 may be approximately the same over substantially the whole extent of a radiation collector 341. This may in particular be the case when the pitch 803 and the depth D are configured such that the radiation collector acts as a diffraction grating to infrared radiation. This advantageously reduces the amount of infrared radiation which is reflected to the intermediate focus 16 and thus reduces the amount of infrared radiation which is incident on the optical components of a lithographic apparatus LA.

In order to configure a radiation collector 341 such that it acts as a diffraction grating to infrared radiation having a wavelength ?m, the depth D of the periodic structure of the radiation collector 341 may be set according to equation (2).

D=cos θ(n+¼)λ_{IR} (2)
Where n is an integer number and θ is the angle of incidence of radiation (having a wavelength m) on the reflective surfaces 801 of a radiation collector 341. This may cause infrared radiation beams which are reflected from adjacent reflective surfaces 801 to have a difference in path length of approximately (n+½)λ_{IR}. Infrared radiation beams which are reflected from adjacent reflective surfaces 801 will therefore be out of phase with each other and will destructively interfere with each other, thereby reducing the amount of infrared radiation which is reflected to an intermediate focus 16. Instead infrared radiation is diffracted to form higher order interference fringes which do not propagate towards the intermediate focus 16.

In an embodiment a radiation collector 341 may, for example, be configured to act as a diffraction grating to infrared radiation having a wavelength λ_{IR} of approximately 10 μm (e.g. 10.6 μm). The infrared radiation may be normally incident on the radiation collector 341. In this embodiment the minimum depth D (when n=0 in equation (2)) which satisfies equation (2) is approximately 2.65 μm. For a value of n=50 in equation (2) the depth D is approximately equal to 0.53 mm.

In another embodiment infrared radiation having a wavelength of approximately 10 μm may be incident on a radiation collector 341 with an angle of incidence θ of approximately 20°. In this embodiment the minimum depth D (when n=0 in equation (2)) which satisfies equation (2) is approximately 2.5 μm. For a value of n=50 in equation (2) the depth D is approximately equal to 0.5 mm.

In an embodiment a radiation collector 341 may have a pitch 803 which is approximately equal to 1 mm. The radiation collector 341 may, for example, have a depth D which is approximately equal to 0.5 mm. Such a radiation collector 341 may act as a diffraction grating to infrared radiation (e.g. radiation having a wavelength of approximately 10 μm). A radiation collector 341 may, for example comprise more than 200 reflective surfaces. For example a radiation collector 341 may comprise approximately 240 reflective surfaces 801 which are each coincident with a different one of approximately 240 ellipsoids.

Configuring a radiation collector 341 as was described above such that it acts as a diffraction grating to infrared radiation is advantageous over prior art radiation collectors which act as a diffraction grating to infrared radiation. FIG. 10b is a schematic depiction of a close up view of a portion of a prior art radiation collector 810. The radiation collector 810 comprises a reflective surface 811 which is configured to reflect EUV radiation 815 which is incident on the radiation collector 810. The reflective surface 811 comprises a series of troughs 812 in the reflective surface which are configured to cause the reflective surface to act as a diffraction grating to infrared radiation.

During the manufacture of a radiation collector 810 which is configured to reflect EUV radiation, the reflective surface 810 of a radiation collector may be polished in order to increase the reflectivity of the surface. During polishing of the reflective surface 811 which is depicted in FIG. 10b some regions of the troughs 812 in the reflective surface 811 may not be reached by equipment which is used to polish the reflective surface 811. As a result some of the reflective surface 811 which forms the troughs 812 may not be polished. For example the corners of the troughs 812 may not be polished. This may result in, for example, approximately 10% of the reflective surface 811 not being polished during polishing of the radiation collector 810. As a result the reflectivity of the unpolished regions of the reflective surface 811 will be reduced and therefore less EUV radiation will be collected by the radiation collector and provided to a lithographic apparatus LA.

In contrast to the prior art radiation collector 810 depicted in FIG. 10b, substantially the entire extent of the reflective surfaces 801 of the radiation collector 341 depicted in FIG. 10a may be accessible during polishing of the radiation collector 341. This may increase the reflectivity of the reflective surfaces 801 and may allow more EUV radiation to be reflected to the intermediate focus 16 of a radiation source SO. The accessibility of the reflective surfaces 801 during polishing of the radiation collector 810 may be improved by for example undercutting the intermediate surfaces 802 behind the reflective surfaces 802. FIG. 10c is schematic depiction of a radiation collector 341 in which the intermediate surfaces 802 are undercut behind the reflective surfaces 802. This may improve the accessibility of the reflective surfaces 802 during polishing of the radiation collector 341 and may therefore increase the reflectivity of the radiation collector 341.

Reflective surfaces of a radiation collector (e.g. the reflective surfaces 802 of the radiation collector 341 depicted in FIG. 10a) are configured to reflect radiation in a given wavelength range. For example, a radiation collector in an EUV radiation source SO comprises reflective surfaces which are configured to reflect EUV radiation. Some of the infrared radiation which is incident on a radiation collector may therefore be absorbed by the radiation collector as opposed to being reflected by the radiation collector (since the reflective surfaces of the radiation collector are not configured to reflect infrared radiation). For example, in an EUV radiation source SO, a radiation collector may absorb approximately 17 kW of power. Absorption of infrared radiation by the radiation collector may cause heating of the radiation collector. It may be desirable to cool a radiation collector in order to avoid excess heating of the radiation collector. For example, a coating which may be provided on a radiation collector may become damaged above a threshold temperature. It is therefore desirable to maintain the temperature of the radiation collector to below the threshold temperature in order to avoid damage to the radiation collector, thereby extending the useful lifetime of the radiation collector. The threshold temperature below which it is desirable to maintain a radiation collector may, for example, be approximately 60° C.

FIG. 11 is a schematic depiction of a radiation collector 820 which is provided with a cooling system 832. The radiation collector 820 comprises a mirror structure 831 which is configured to reflect EUV radiation 835 which is incident upon it. The mirror structure 831 comprises a substrate 822, a smoothing layer 821 and a multilayer structure 828. The substrate 822 may, for example, be machined to include troughs (not shown) such that the mirror structure 831 acts as a diffraction grating to infrared radiation. It will be appreciated that in an embodiment in which the substrate 822 includes troughs, some portions of the smoothing layer 821 and the multilayer structure 828 will be positioned in the troughs of the substrate 822 and thus the smoothing layer 821 and the multilayer structure 828 will also include troughs (not shown). Such an arrangement may, for example, be used to construct a radiation collector similar to the radiation collector depicted in FIG. 10b. However it will be appreciated that in an embodiment in which a diffraction grating is formed from a plurality of reflective surfaces which are coincident with a plurality of ellipsoids (e.g. the radiation collectors 341 depicted in FIGS. 10a and 10c) the individual reflective surfaces are not provided with troughs since it is the combination of the plurality of reflective surfaces which forms a diffraction grating to infrared radiation. As such the portion of the radiation collector 820 which is depicted in FIG. 11 may represent a portion of a single reflective surface of a plurality of reflective surfaces (which together form a diffraction grating to infrared radiation) and thus the substrate 822, the smoothing layer 821 and the multilayer structure 828 may not be provided with troughs.

The substrate 822 may, for example, comprise SiSiC. SiSiC has a low coefficient of thermal expansion (e.g. <5 μm/mK) and has a high thermal conductance (e.g. 150 W/mK). SiSiC may therefore undergo relatively little expansion when heated and may efficiently conduct heat away from the mirror structure 831 (e.g. by conduction to the cooling system 832).

The substrate 822 is provided with a smoothing layer 821. The smoothing layer may improve the quality (e.g. decrease the surface roughness) of the surface on which the multilayer structure 828 is deposited. This may in particular be important in embodiments in which the substrate 822 is provided with troughs. However in embodiments in which the substrate 822 is not provided with troughs, the smoothing layer 821 may optionally not be included such that the multilayer structure is provided directly on the substrate 822.

The smoothing layer 821 may, for example, comprise nickel phosphate. Nickel phosphate has a coefficient of thermal expansion of approximately 13 μm/mK. In an embodiment in which the substrate 822 comprises SiSiC and the smoothing layer 821 comprises nickel phosphate there is therefore a relatively large difference between the coefficient of thermal expansion of the substrate 822 and the coefficient of thermal expansion of the smoothing layer 821. This causes the substrate 822 and the smoothing layer 821 to expand by different amounts when the mirror structure 831 is heated (e.g. by absorption of infrared radiation). This may undesirably induce stress in the mirror structure 831 which may damage the mirror structure 831. It is therefore desirable to use a substrate 822 material and a smoothing layer 821 material whose coefficients of thermal expansion are more closely matched in order to reduce an induced stress in the mirror structure 831.

For example, the substrate 822 may comprise copper and the smoothing layer 821 may comprise nickel phosphate. Copper has a coefficient of thermal expansion of approximately 16 μm/mK and therefore the difference between the coefficient of thermal expansion of copper and the coefficient of thermal expansion of nickel phosphate is only approximately 3 μm/mK (compared with >8 μm/mK in an embodiment in which the substrate 822 comprises SiSiC). Copper is additionally advantageous for use as a substrate 822 since it has a high thermal conductance of approximately 390 W/mK.

In an alternative embodiment the substrate 822 may, for example, comprise Al Si-40 and the smoothing layer 821 may, for example, comprise nickel phosphate. In this embodiment the difference between the coefficient of thermal expansion of the substrate 822 and the coefficient of thermal expansion of the smoothing layer 821 may, for example, be less than 0.5 μm/mK.

The multilayer structure 828 may, for example, comprise a plurality of alternating pairs of a first and second material which have different refractive indices. The refractive indices and thicknesses of the alternating layers of the first and second material may be configured such that the multilayer structure acts as a Bragg reflector to EUV radiation. The first and second materials may, for example, comprise molybdenum and silicon.

The cooling system 832 which is configured to cool the mirror structure 831 is a two-phase cooling system in which a coolant transitions between a liquid phase state and a gaseous phase state. The coolant may, for example, comprise methanol. The cooling system 832 comprises a porous structure configured to receive the coolant in its liquid phase state. The porous structure 823 may comprise a material with a high thermal conductance. The porous structure 823 may, for example, comprise porous copper comprising a layer of copper through which a capillary structure extends. The porous structure 823 may alternatively comprise another material (e.g. a different metal) through which a capillary structure extends. The porous structure 823 may, for example, be sealed on the substrate 822 side of the porous structure to prevent the liquid phase coolant from leaking from the porous structure 823. The porous structure 823 may, for example, be sealed with a copper sheet. The porous structure 823 and a sealing copper sheet may, for example, be manufactured using 3D printing techniques.

The high thermal conductance of the porous structure 823 reduces a thermal length between the mirror structure 831 and the liquid phase coolant in the porous structure 823 such that heat may be efficiently conducted from the mirror structure 831 to the liquid phase coolant. Heat which is conducted to the liquid phase coolant may induce a phase change of the coolant to a vapour phase state. A phase change of the coolant from a liquid to a vapour phase state absorbs heat energy and thus acts to cool the mirror structure 831.

Coolant which has undergone a phase change from a liquid phase state to a vapour phase state moves to a transition region 824 of the cooling system 832. The vapour phase coolant moves through the transition region 824 and to a condenser 825. The movement of the vapour phase coolant through the transition region 824 is indicated by arrows 826 in FIG. 11. The condenser 825, condenses the vapour phase coolant so as to force the vapour phase coolant to undergo a phase change to a liquid phase state. The condenser absorbs any heat energy which is released during the phase change and transports the heat away from the mirror structure 831.

Coolant which has been condensed in the condenser 825 to a liquid phase state is output from the condenser 825 for entry into the porous structure 823 (represented by arrows 827 in FIG. 11). The transition region 824 may, for example, comprise one or more channels through which liquid phase coolant may be transported from the condenser 825 to the porous structure 822.

The movement of the coolant through the porous structure 823, the transition region 824 and the condenser 825 forms a two-phase cooling cycle which transfers heat from the mirror structure 831 to the condenser 825 and therefore acts to cool the mirror structure 831.

Capillary action in the porous structure 832 may ensure that the liquid phase coolant is substantially evenly distributed throughout the porous structure 823 which may result in a substantially uniform cooling being provided to the mirror structure 831. This is advantageous since it reduces significant temperature gradients forming in the mirror structure 831. Temperature gradients in the mirror structure 831 may lead to localized hot spots which are at a higher temperature than surrounding regions of the mirror structure 831. This may cause some regions of the mirror structure 831 to expand to a greater extent than other regions of the mirror structure 831. This induces stress in the mirror structure 831 and may distort the shape of the mirror structure 831.

In this respect the cooling system 832 described above is particularly advantageous when compared to, for example, providing cooling to a mirror structure by flowing a liquid coolant (e.g. water) through coolant channels positioned in thermal contact with the mirror structure 831. Such an arrangement results in an inconsistent thermal length between portions of the mirror structure 831 and the coolant channels, which causes undesirable temperature gradients in the mirror structure 831.

The cooling system 832 described above is further advantageous over providing liquid coolant channels because the pressure of the coolant in the cooling system 832 may be lower than the pressure of liquid coolant in liquid coolant channels. For example, in an embodiment in which the coolant comprises methanol, the pressure of the methanol in the cooling system 832 may be approximately 0.2 bar. Such a pressure may be sufficiently low that no substantial pressure forces are exerted by the methanol on the mirror structure 831 which may lead to deformation of the mirror structure 831. By contrast, the pressure of a liquid coolant in a coolant channel may be substantially higher which may lead to deformation of regions of the mirror structure due to pressure forces in the coolant channel. Additionally the use of a two-phase coolant (e.g. methanol) in the cooling system 832 reduces the risk of corrosion of components of a cooling system and/or leakage of coolant from the cooling system when compared to, for example, water flowing through coolant channels.

For the reasons given above a two-phase cooling system such as the cooling system 832 may be used to advantageously provide effective cooling to a radiation collector 820. Such a cooling system may reduce deformation of a mirror structure of a radiation collector and may therefore increase the amount of radiation which is collected by the radiation collector. Additionally, a two-phase cooling system may reduce any damage to the radiation collector and may therefore prolong the useful lifetime of the radiation collector, thereby reducing costs.

A two-phase cooling system may be used, for example, to cool any of the embodiments of radiation collectors which are described above and which are depicted in the figures, Additionally a two-phase cooling system may advantageously be used to cool prior art radiation collectors such as radiation collectors which are formed according to a single ellipsoid. A two-phase cooling system may also be advantageously used to cool other optical components of a lithographic apparatus which are susceptible to being heated during operation.

The term “EUV radiation” may be considered to encompass electromagnetic radiation having a wavelength within the range of 5-20 nm, for example within the range of 13-14 nm. EUV radiation may have a wavelength of less than 10 nm, for example within the range of 5-10 nm such as 6.7 nm or 6.8 nm.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A radiation collector comprising:
a plurality of reflective surfaces, wherein each of the plurality of reflective surfaces is coincident with part of one of a plurality of ellipsoids,
wherein the plurality of ellipsoids have in common a first focus and a second focus,
each of the plurality of reflective surfaces coincident with a different one of the plurality of ellipsoids, and
the plurality of reflective surfaces are configured to receive radiation originating from the first focus and reflect the radiation to the second focus.

2. The radiation collector of claim 1, wherein the reflective surfaces are disposed around an optical axis of the radiation collector.

3. The radiation collector of claim 1, wherein the reflective surfaces extend circumferentially around the optical axis.

4. The radiation collector of claim 1, wherein the plurality of reflective surfaces have lengths that cause the radiation collector to act as a diffraction grating to infrared radiation.

5. (canceled)

6. The radiation collector of claim 1, wherein the plurality of reflective surfaces are joined by one or more intermediate surfaces.

7. The radiation collector of claim 6, wherein the intermediate surfaces each have a length of around cos θ(n+¼)λ_{IR} where n is an integer, λ_{IR} is the wavelength of infrared radiation to which the radiation collector acts as a diffraction grating and θ is the angle of incidence of infrared radiation on the reflective surfaces of the radiation collector.

8. (canceled)

9. The radiation collector of claim 6, wherein each intermediate surface is arranged substantially parallel to a direction from the first focus to the corresponding intermediate surface.

10. The radiation collector of claim 6, wherein the intermediate surfaces are undercut behind the reflective surfaces.

11. The radiation collector of claim 6, wherein one or more holes are provided in at least one of the one or more intermediate surfaces.

12. The radiation collector of claim 1, wherein the plurality of reflective surfaces comprises more than 10 reflective surfaces.

13. The radiation collector of claim 1, wherein an inner reflective surface of the plurality of the reflective surfaces is coincident with an inner ellipsoid of the plurality of ellipsoids.

14. The radiation collector of claim 2, wherein the distance of each of the plurality of reflective surfaces from the optical axis increases with the size of the ellipsoid which each reflective surface is coincident with.

15. The radiation collector of claim 2, wherein the radiation collector is configured such that an available length along the optical axis is provided in which a contaminant trap may be positioned in between the radiation collector and the first and second focuses.

16. (canceled)

17. An apparatus comprising a cooling system and a reflector, wherein the cooling system is configured to cool the reflector, the cooling system comprising:
a porous structure situated in thermal contact with the radiation collector, wherein the porous structure is configured to receive a coolant in a liquid phase state; and
a condenser configured to receive coolant from the porous structure in a vapour phase state, condense the coolant thereby causing the coolant to undergo a phase change to a liquid phase state and output the condensed coolant in the liquid phase state for entry into the porous structure.

18. The apparatus of claim 17, wherein the porous structure comprises a material through which a capillary structure extends.

19.-20. (canceled)

21. The apparatus of claim 18, wherein the cooling system is configured such that coolant is distributed through the porous structure by capillary action.

22. (canceled)

23. The apparatus of claim 17, further comprising a non-porous sheet configured to seal the porous structure from the reflector.

24. The apparatus of claim 23, wherein the non-porous sheet comprises a non-porous sheet of copper.

25.-28. (canceled)

29. The apparatus of claim 17, wherein a surface of the substrate that is furthest from the porous layer is provided with a smoothing layer configured to provide a smooth surface.

30. (canceled)

31. The apparatus of claim 17, wherein the reflector comprises a radiation collector comprising:
a porous structure situated in thermal contact with the radiation collector, wherein the porous structure is configured to receive a coolant in a liquid phase state; and
a condenser configured to receive coolant from the porous structure in a vapour phase state, condense the coolant thereby causing the coolant to undergo a phase change to a liquid phase state and output the condensed coolant in the liquid phase state for entry into the porous structure.
